(19) United States
(12) Patent Application Publication
(10) Pub. No.: US 2022/0328312 A1
(43) Pub. Date: Oct. 13, 2022

(54) METHOD FOR MANUFACTURING SEMICONDUCTOR ELEMENTS BY METAL LIFT-OFF PROCESS AND SEMICONDUCTOR ELEMENT MANUFACTURED THEREBY

(71) Applicant: KINGRAY TECHNOLOGY CO., LTD., Hsinchu (TW)

(72) Inventors: Cheng-Hsing Tsou, Hsinchu (TW); Ta-Hsiang Chao, Hsinchu (TW); Jung-Sen Hu, Hsinchu (TW)

(21) Appl. No.: 17/401,877

(22) Filed: Aug. 13, 2021

(30) Foreign Application Priority Data
Apr. 9, 2021 (TW) 110113002

(51) Int. Cl. H01L 21/033; G03F 7/20; G03F 7/16; G03F 7/32

(52) U.S. Cl. CPC H01L 21/0331; G03F 7/2004; G03F 7/16; G03F 7/32

(57) ABSTRACT

A method for manufacturing semiconductor elements by a metal lift-off process and a semiconductor element manufactured thereby, include steps of photoresist-coating, exposing, developing, metal-coating, and lift-off. A photoresist layer can be removed with a photoresist stripper. Meanwhile, the metal on the top of the photoresist layer can also be removed when the photoresist layer is removed. The circuit layout required for the semiconductor element can thus be completed without an etching process. In addition, by setting the process parameters, the contour of the photoresist layer can present a certain angle, so that the metal on the surface of the photoresist layer can be completely removed, which saves costs and improves competitiveness.

### BACKGROUND OF INVENTION

### (1) Field of the Present Disclosure

The present disclosure relates to a method for manufacturing semiconductor elements by a metal lift-off process and a semiconductor element manufactured thereby, which increases the efficiency of the manufacturing process, saves costs and reduces production time by simplifying and improving the manufacturing process. Meanwhile, the present disclosure avoids the surface of the substrate from damage caused by metal residues.

### (2) Brief Description of Related Art

In general, when manufacturing semiconductor elements, it is often necessary to use an etching process to etch metal and thus design the necessary circuits. In FIG. 1, a flow chart of a conventional etching process is shown:

First, metal-coating, a surface of a substrate S is coated with a metal layer M.

Secondly, photoresist-coating, a photoresist P is coated on a surface of the metal layer M.

Thirdly, exposing, the photoresist P is exposed by a light source and a photomask.

Fourth, development, an unexposed of the photoresist P is etched by a developer; then, the photoresist P remaining on the surface of the metal layer M is formed into a photoresist layer P′ with a pattern.

Fifth, etching, the metal layer M which is not covered by the photoresist layer P′ is removed with an etching liquid.

Sixth, lift-off, the photoresist layer P′ is lifted off from the surface of the metal layer M in such a way that a circuit is formed by the metal layer remaining on the surface of the substrate S.

In the conventional method for manufacturing semiconductor elements, an undesired metal area is removed by etching, and a desired metal area is remained to form a circuit. However, in order to etch all metals cleanly and without metal residues, various metal etching liquids, such as HF, HNO₃, H₂O₂, KOH, NH₄OH, H₂SO₄, DHF, H₃PO₄, are required to achieve a better etching effect.

However, the etching method for removing the metal layer has the following disadvantages:

First, the etching cost of removing the metal layer deposited by the sputtering process or the evaporation process is relatively high, due to the expensive etching machine and the metal etching liquid.

Second, in the case of special corrosion-resistant metal layers, metal residues arise due to the problem of poor etchability. To improve the performance of the metal etching liquid, it is treated by increasing the concentration of the etching liquid or increasing the immersion time. However, the highly concentrated etching process can also damage the surface of the substrate, which leads to a reduction in the yield.

Thirdly, the additional etching process increases the production time and cost (such as electricity, man-hours, manpower, etc.).

### SUMMARY OF INVENTION

It is a primary object of the present disclosure to provide a method for manufacturing semiconductor elements by a metal lift-off process and a semiconductor element manufactured thereby, which avoids metal residues arising from the etching process and the high production costs due to the high costs caused by the machine.

According to the present disclosure, a photoresist layer with a pattern is formed on a surface of a substrate by photoresist-coating, exposing, development, and other processes, the substrate being provided with a metal coating processes, whereupon the photoresist layer is removed with a photoresist stripper (PR-Strip, made from NMP, DMSO, and glycol ether). When removing the photoresist layer with the photoresist stripper, the metal located on top of the photoresist layer is also removed. Moreover, the present disclosure enables the photoresist layer to form a unique angle so that the side of the photoresist layer is not easily covered with metal, thereby avoiding metal residue caused by improper metal etching. In this way, the metal removal by etching can be abandoned, and the expensive etching machine and the etching liquid costs can be saved. In addition, the process is simplified, the production time and costs are greatly reduced. Furthermore, the competitive advantage is considerably improved.

### BRIEF DESCRIPTION OF THE DRAWINGS

FIG. 1 is a flow chart of a conventional etching process.

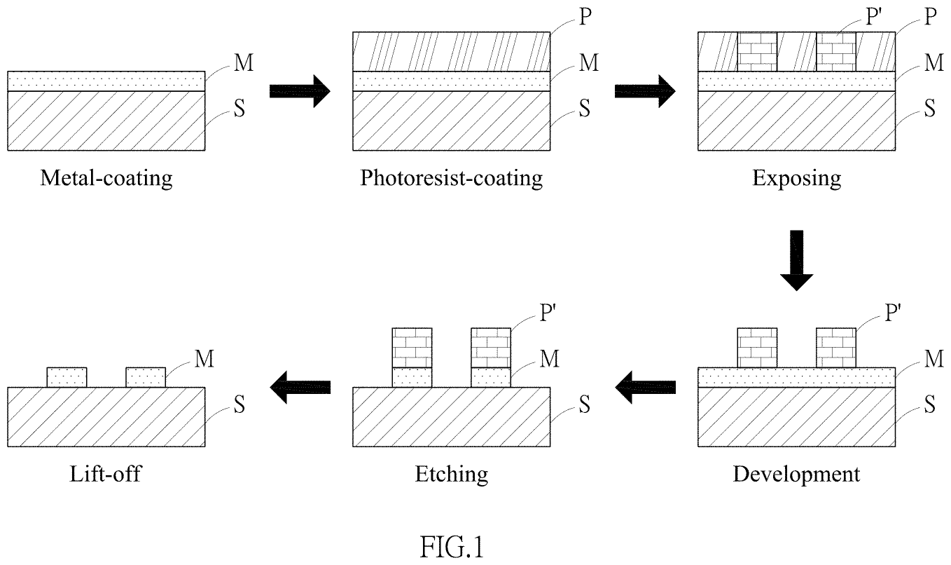

FIG. 2 is a block flow diagram of a method according to the present disclosure.

FIG. 3 is a schematic drawing I of the implementation of the present disclosure.

FIG. 4 is the relationship between the coating thickness and the spin speed of the spin coating in a diagram according to the present disclosure.

FIG. 5 is a schematic drawing II of the implementation of the present disclosure.

FIG. 6 is the relationship between the photoresist reaction thickness and the exposure energy in a diagram according to the present disclosure.

FIG. 7 is a schematic drawing III of the implementation of the present disclosure.

FIG. 8 is a schematic drawing IV of the implementation of the present disclosure.

FIG. 9 is a schematic drawing V of the implementation of the present disclosure.

FIG. 10 is a schematic drawing I of another embodiment of the present disclosure.

FIG. 11 is a schematic drawing II of another embodiment of the present disclosure.

FIG. 12 is a schematic drawing of another embodiment of the present disclosure.

FIG. 13 is a table of process parameters according to the present disclosure.

### DETAILED DESCRIPTION OF PREFERRED EMBODIMENTS

A metal lift-off system used in a method according to the present disclosure at least includes a central control module which is connected to a photoresist-coating module, an exposure module, a development module, a metal coating module, and a lift-off module. The function of each module is described as follows:

The central control module is used to operate the metal lift-off system, to control the operation of the above modules, and can be used by the operator to monitor, operate, and adjust the metal lift-off system. The central control module fulfills functions such as logical operation, temporary storage of operation results, and storage of execution command positions. It can be a CPU (central processing unit), but is not limited thereto.

The photoresist-coating module is used to coat a photoresist on a substrate. The photoresist-coating module can be a spin coater or a sprayer, etc. Any device that can apply the photoresist evenly to the substrate is applicable, to which the invention is not intended to be limited. The photoresist can be a positive-working photoresist or a negative-working photoresist. Optionally, the photoresist-coating module can be carried out a soft-bake process after the photoresist-coating has been completed.

The exposure module is used to expose the photoresist with an exposure parameter, a light source, and a photomask with a pattern and then to generate different patterned effects after rinsed by a developer. For example, an unexposed part of the negative-working photoresist dissolves in the developer, while an exposed part does not dissolve in the photoresist developer. The exposure conditions can be adjusted as needed. The exposure module can be, for example, an aligner exposure system, a stepper exposure system, or a scanner exposure system, but is not limited thereto. Optionally, the exposure module can be carried out a baking process after the exposing has been completed.

The development module is used to rinse the exposed photoresist with the developer to form a patterned photoresist layer. It can be done by spraying, dipping, washing, ultrasonic vibration, etc., or any combination of these. Optionally, the development module is used to rinse the developed substrate with a deionized water in order to remove the developer remaining on the substrate and the photoresist layer. A hard-bake process can then be carried out.

The metal coating module is used to coat a first metal layer and a second metal layer on the substrate and the photoresist layer by a PVD (Physical Vapor Deposition) process and a CVD (Chemical Vapor Deposition) process.

The lift-off module is used to remove the photoresist layer by a dry photoresist stripping process (PR-Strip). When the photoresist layer is removed, the first metal layer, which adheres to the top of the photoresist layer, is also removed, so that only the second metal layer remains on the surface of the substrate. A photoresist stripper includes, but is not limited thereto, a combination of solvents such as N-methylpyrrolidone [NMP], dimethyl sulfide [DMSO], and glycol ether.

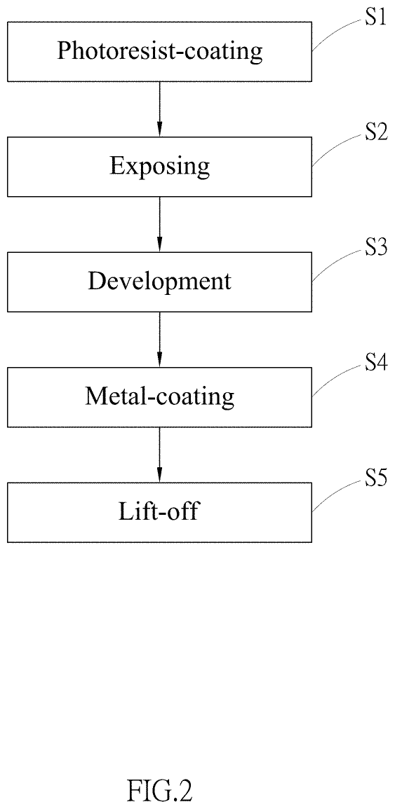

As shown in FIG. 2, a manufacturing method according to the present disclosure includes the following steps:

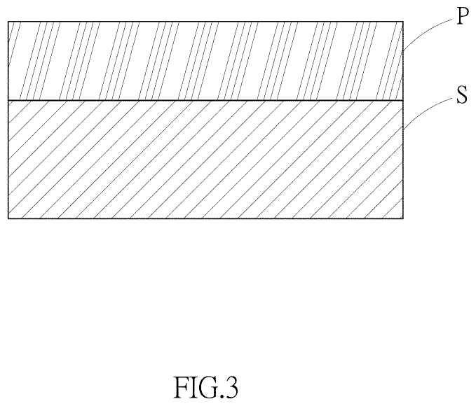

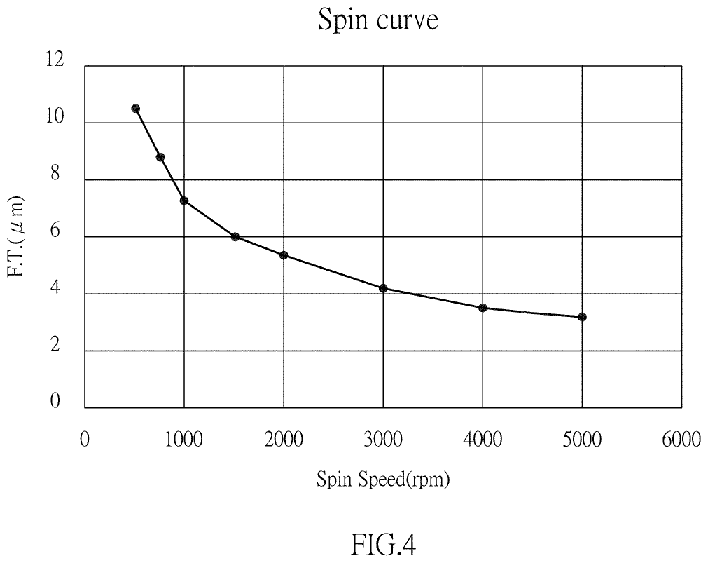

Step S1: Photoresist-coating, wherein, as shown in FIG. 3, a photoresist P is evenly coated on a substrate S by the metal lift-off system. The photoresist P is preferably designed as a negative-working photoresist. The photoresist P consists of resin, sensitizer, and solvent, and is coated in a manner of spin coating. The relationship between speed parameters and a coating thickness is shown in FIG. 4. The coating thickness preferably ranges from 1 μm to 15 μm. After the photoresist P is completely coated, a soft-bake process is carried out at a temperature of 70° C. to 120° C. for 60 seconds to 90 seconds.

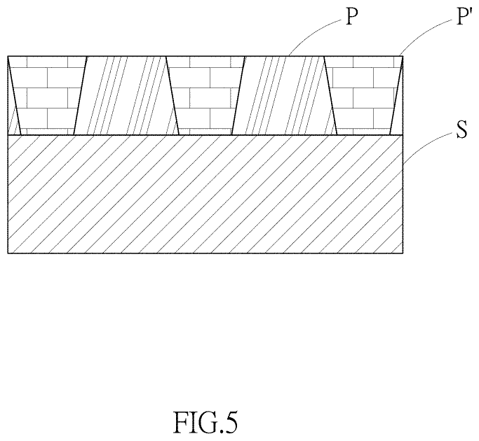

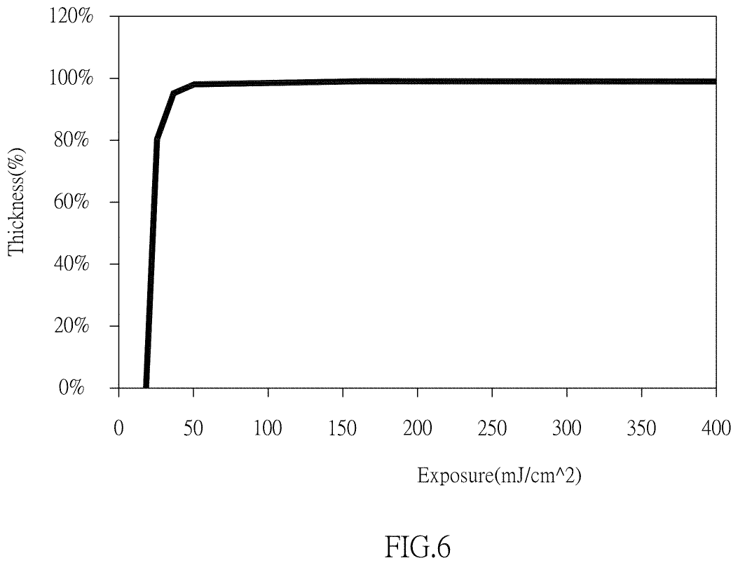

Step S2: Exposing, wherein, as shown in FIG. 5, the photoresist P coated on the substrate S is exposed by the metal lift-off system with an exposure process parameter, a light source, and a photomask with a pattern, so that the photoresist is formed as a patterned photoresist layer F. In the case of negative-working photoresist P, an exposed part of the photoresist P is preferably shaped as the photoresist layer P′, and an unexposed part of the photoresist P remaining as the photoresist P. The exposure parameter preferably includes an aligner exposure system with a proximity broadband ranging from 350 nm to 450 nm, or a stepper exposure system with a lamp source which is designed as a g-line, a K-line, or an i-line, a gap ranging from 0 nm to 50 nm, and an exposure energy ranging from 40 mJ/cm² to 450 mJ/cm². With respect to the exposure conditions, the sensitivity curve of the exposure energy and a percentage of the photoresist thickness is shown in FIG. 6. After exposing, a baking process is preferably carried out at a temperature of 40° C. to 100° C. for 60 seconds to 90 seconds.

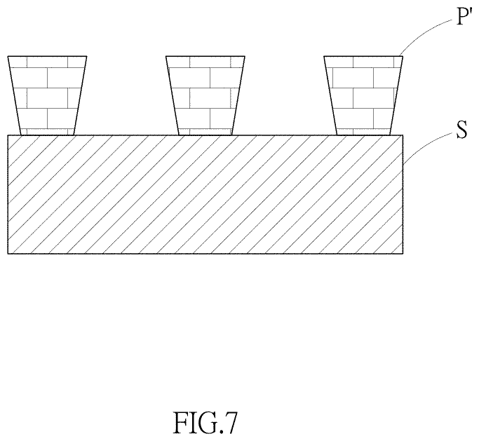

Step S3: Development, wherein, as shown in FIG. 7, the unexposed photoresist P coated on the substrate S is rinsed by the metal lift-off system with a developer. The developer may be a solution containing 1 wt % to 5 wt % of tetramethylammonium hydroxide [TMAH], and the unexposed photoresist P rinsed with the developer is carried out for 40 seconds to 120 seconds. Optionally, a deionized water can be used for rinse for 10 seconds to 60 seconds. Furthermore, a hard-bake process can be carried out at a temperature of 100° C. to 250° C. for 5 minutes to 20 minutes. The patterned photoresist layer P′ is shown on the surface of the substrate S after rinse.

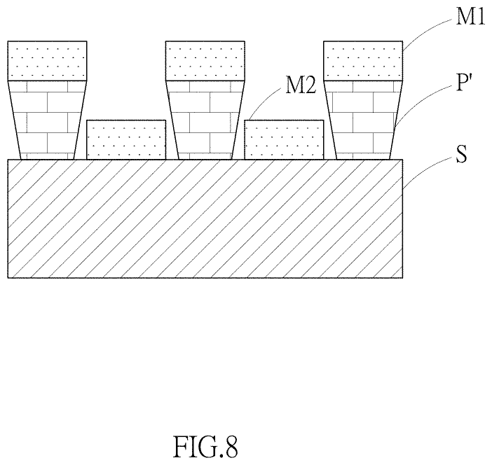

Step S4: Metal-coating, wherein, as shown in FIG. 8, the metal lift-off system uses PVD (Physical Vapor Deposition) process to coat the photoresist layer P′ with a first metal layer M1, and the substrate S with a second metal layer M2.

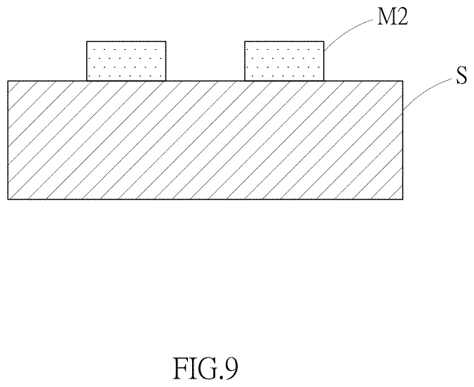

Step S5: Lift-off, wherein, as shown in FIG. 9, a photoresist stripper is used in the metal lift-off system to lift-off the photoresist layer P′. When the photoresist layer P′ is removed, the first metal layer M1 adhering to the top of the photoresist layer P′ is also removed, and only the second metal layer M2 adhering to the surface of the substrate S is remained. The remaining second metal layer M2 is a circuit to be designed for a semiconductor element. The photoresist stripper includes, but is not limited to, a combination of solvents such as N-methylpyrrolidone [NMP], dimethyl sulfide [DMSO], and glycol ether.

With reference to FIGS. 3, 5, and 7 to 9, the semiconductor element manufactured by the manufacturing method according to the present disclosure includes the substrate S and the second metal layer M2. The surface of the substrate S is coated with the photoresist P. The photoresist P coated on the substrate S is exposed with a light source and a patterned photomask in such a way that the exposed part of the photoresist P is formed into the photoresist layer P′, while the unexposed part of the photoresist P remains as the photoresist P. If the photoresist P is designed as a negative-working photoresist P, the exposed part serves as the photoresist layer P′. If the photoresist P is designed as a positive-working photoresist P, the unexposed part serves as the photoresist layer P′. The photoresist P is rinsed with a developer, so that the remaining substrate S and the remaining photoresist layer V can form a patterned structure. A metal is coated on the surface of the substrate S and the photoresist layer P′ by the PVD process or the CVD process. The metal coated on a surface of the photoresist layer P′ is designed as a first metal layer M1, and the metal coated on the surface of the substrate S is designed as a second metal layer M2. The photoresist layer P′ can be removed with a photoresist stripper. Meanwhile, the first metal layer M1 will also be removed together with the photoresist layer P′. By removing the photoresist layer P′, the second metal layer M2 on the surface of the substrate S can be formed as a circuit.

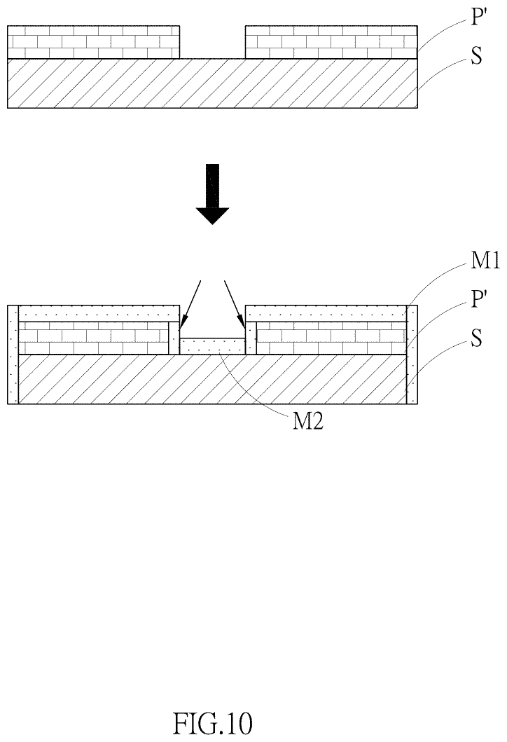

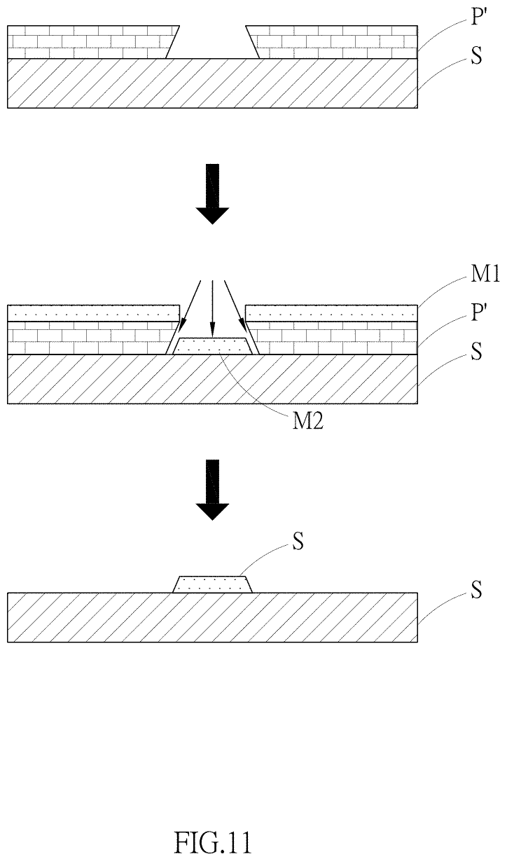

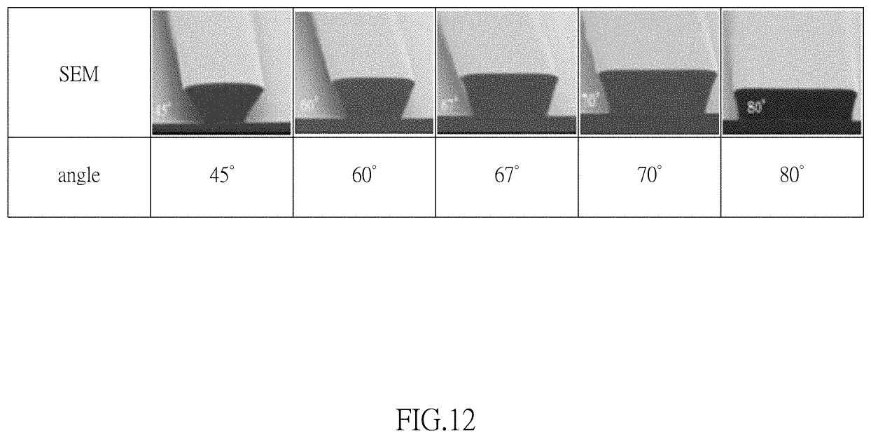

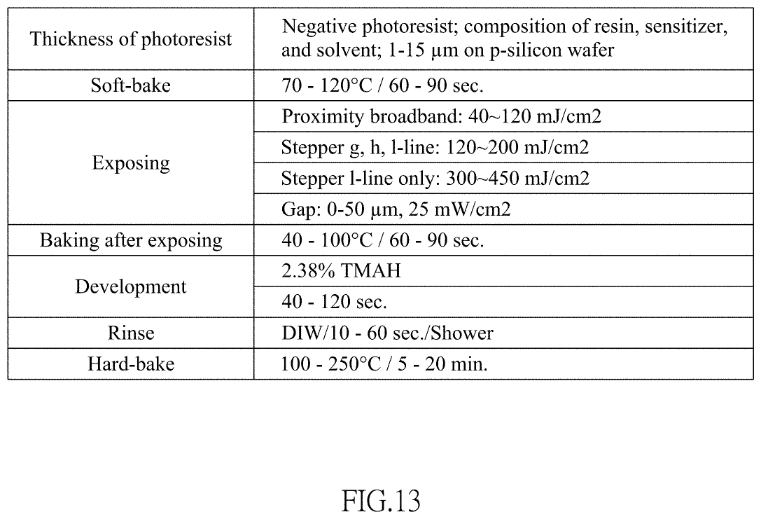

As shown in FIGS. 10 and 11 together with FIGS. 3 to 9, the photoresist layer P′ can be formed into a tapered shape from top to bottom by coordinating various process parameters in Photoresist-coating S1, Exposing S2, and Development S3 according to the present disclosure. In this way, after the Metal-coating S4 has been performed, the photoresist layer P′ is prevented from being completely covered, as shown in FIG. 10. As shown in FIG. 11, it is not easy that the first metal layer M1 and the second metal layer M2 cover the side surfaces of the photoresist layer F. In the other hand, the first metal layer M1 and the second metal layer M2 are only coated on the exposed surface of the substrate S and the photoresist layer F. Referring to FIG. 12, an angle between the photoresist layer V and the substrate S is preferably 40° to 100°. In this way, the photoresist layer V can be easily lifted off when performing the step S5. Since the first metal layer M1 and the second metal layer M2 are not located on the side surface, it avoids that the problem with lift-off arises and the metal residues are produced. Therefore, the etching process is saved. A table for the process parameters according to the present disclosure is shown in FIG. 13. A p-type silicon wafer is used as the substrate. The coated photoresist P is a negative-working photoresist composed of resin, sensitizer, and solvent. The coating thickness ranges from 1 μm to 15 μm. After the photoresist-coating is completed, a soft-bake process is carried out at a temperature of 70° C. to 120° C. for 60 seconds to 90 seconds. After the soft-bake process, the exposure parameters can be as follows, for example, an aligner exposure system with proximity broadband and an exposure energy ranging from 40 mJ/cm² to 120 mJ/cm²; a stepper exposure system with a g-line, a h-line, an i-line, or a combination thereof and with an exposure energy ranging from 120 mJ/cm² to 200 mJ/cm²; or a stepper exposure system only with l-line and an exposure energy ranging from 300 mJ/cm² to 450 mJ/cm². Moreover, abovementioned stepper exposure system comprises a gap ranging from 0 μm to 50 μm and 25 mW/cm² exposure energy. After exposing, a baking process is carried out at a temperature of 40° C. to 100° C. for 60 seconds to 90 seconds, and it continues to expose afterwards. After exposing, a development process is carried out with 2.38 wt % of tetramethylammonium hydroxide [TMAH] solution for 40 seconds to 120 seconds, and with a deionized water [DIW] to spray and wash for 10 seconds to 60 seconds. After spraying and washing, a hard-bake process is carried out at a temperature of 100° C. to 250° C. for 5 minutes to 20 minutes. The above-mentioned process parameters are only one example to which the invention is not intended to be restricted.

In the method for manufacturing semiconductor elements by the metal lift-off process and the semiconductor element manufactured thereby in the present disclosure, the substrate is successively subjected to photoresist-coating, exposing, development, metal coating, and lift-off, after which the photoresist layer can be removed using the photoresist stripper. In this way, the metal layer on the top of the photoresist layer can also be removed in order to complete the circuit layout of the semiconductor element. In addition, as a result of the arrangement of the process parameters, the photoresist layer tapers from top to bottom in such a way that it is positioned at a certain angle to the substrate. Thus, the photoresist layer is not completely covered by the metal when the step of metal coating is carried out. In this way, the photoresist layer can be lifted off with the photoresist stripper. Meanwhile, the circuit layout can be completed without an etching process. Accordingly, it is actually possible to eliminate the etching process, thereby saving the etching cost and effectively improving the competitive advantage.

### REFERENCE SIGN

S1 photoresist-coating
S2 exposing
S3 development
S4 metal coating
S5 lift-off
S substrate
P photoresist
P′ photoresist layer
M metal layer
M1 first metal layer
M2 second metal layer

What is claimed is:

1. A method for manufacturing semiconductor elements by a metal lift-off process, through which a layout of a circuit on a substrate is completed, comprising following steps:
photoresist-coating, the substrate being coated with a photoresist;
exposing, the photoresist being exposed with a light source, a photomask, and an exposure parameter such that a photoresist layer with a pattern is formed on a surface of the substrate;
development, the photoresist after exposing being rinsed with a developer such that the photoresist layer is shown;
metal-coating, a surface of the photoresist layer being coated with a first metal layer, while the surface of the substrate is coated with a second metal layer; and
lift-off, the photoresist layer being removed with a photoresist stripper such that the first metal layer is removed together with the photoresist layer, and the second metal layer being remained to form the circuit.

2. The manufacturing method as claimed in claim 1, wherein, in the step of photoresist-coating, the photoresist is a negative photoresist.

3. The manufacturing method as claimed in claim 1, wherein, in the step of photoresist-coating, a coating thickness of the photoresist ranges from 1 μm to 15 μm.

4. The manufacturing method as claimed in claim 1, wherein the step of photoresist-coating comprises a soft-bake process which is carried out at a temperature of 70° C. to 120° C. for 60 seconds to 90 seconds.

5. The manufacturing method as claimed in claim 1, wherein, in the step of exposing, the exposure parameter comprises a proximity broadband ranging from 350 nm to 450 nm.

6. The manufacturing method as claimed in claim 1, wherein, in the step of exposing, the exposure parameter comprises an aligner exposure system, a stepper exposure system, or a combination thereof.

7. The manufacturing method as claimed in claim 1, wherein, in the step of exposing, the exposure parameter comprises a lamp source which is a g-line, a h-line, an i-line, or a combination thereof.

8. The manufacturing method as claimed in claim 1, wherein, in the step of exposing, the exposure parameter comprises a proximity exposure mode.

9. The manufacturing method as claimed in claim 1, wherein, in the step of exposing, the exposure parameter comprises a gap ranging from 0 μm to 50 μm.

10. The manufacturing method as claimed in claim 1, wherein, in the step of exposing, the exposure parameter comprises an exposure energy ranging from 40 mJ/cm² to 450 mJ/cm².

11. The manufacturing method as claimed in claim 1, wherein, in the step of exposing, the step of exposing comprises a baking process which is carried out at a temperature of 40° C. to 100° C. for 60 seconds to 90 seconds.

12. The manufacturing method as claimed in claim 1, wherein, in the step of development, the developer is 1 wt % to 5 wt % tetramethylammonium hydroxide solution.

13. The manufacturing method as claimed in claim 1, wherein, in the step of development, the photoresist after exposing being rinsed with the developer is carried out for 40 seconds to 120 seconds.

14. The manufacturing method as claimed in claim 1, wherein, in the step of development, the photoresist after exposing being rinsed with a deionized water are carried out for 10 seconds to 60 seconds after rinsed with the developer.

15. The manufacturing method as claimed in claim 1, wherein, in the step of development, the step of development comprises a hard-bake process carried out at a temperature of 100° C. to 250° C. for 5 minutes to 20 minutes.

16. The manufacturing method as claimed in claim 1, wherein, in the step of development, the photoresist layer after development is formed into a tapered shape from top to bottom.

17. The manufacturing method as claimed in claim 16, wherein, in the step of development, an angle between the patterned photoresist layer and the substrate ranges from 40° to 100°.

18. The manufacturing method as claimed in claim 1, wherein, in the step of lift-off, the photoresist stripper comprises a combination of N-methylpyrrolidone, dimethyl sulfide, and glycol ether.

19. A semiconductor element manufactured by a method for manufacturing semiconductor elements by a metal lift-off process, provided with a circuit formed by a photoresist layer formed by exposing a photoresist, comprising:
a substrate;
the photoresist coated on a surface of the substrate and exposed by a light source through a patterned photomask, wherein an unexposed part of the photoresist is removable with a developer;
the photoresist layer being removable with a photoresist stripper;
a first metal layer formed on a surface of the photoresist layer and being removable together with the photoresist layer; and
a second metal layer formed on the surface of the substrate to form the circuit.

20. The semiconductor element as claimed in claim 19, wherein the photoresist is a negative-working photoresist.

21. The semiconductor element as claimed in claim 19, wherein the photoresist comprises a combination of resin, sensitizer, and solvent.

22. The semiconductor element as claimed in claim 19, wherein a coating thickness of the photoresist ranges from 1 μm to 15 μm.

23. The semiconductor element as claimed in claim 19, wherein the developer is a tetramethylammonium hydroxide solution containing 1 wt % to 5 wt %.

24. The semiconductor element as claimed in claim 19, wherein the photoresist layer is formed into a tapered shape from top to bottom.

25. The semiconductor element as claimed in claim 24, wherein an angle between the photoresist layer and the substrate ranges from 40° to 100°.

26. The semiconductor element as claimed in claim 19, wherein the photoresist stripper comprises a combination of N-methylpyrrolidone, dimethyl sulfide, and glycol ether.
